(19) United States
(12) Patent Application Publication
(10) Pub. No.: US 2023/0413472 A1
(43) Pub. Date: Dec. 21, 2023

(54) DYNAMIC NOISE CONTROL FOR ELECTRONIC DEVICES

(71) Applicant: Apple Inc., Cupertino, CA (US)

(72) Inventors: Laura M. CAMPO, Santa Clara, CA (US); David A. SUMBERG, San Francisco, CA (US); Michael J. ROCKWELL, Palo Alto, CA (US)

(21) Appl. No.: 18/135,102

(22) Filed: Apr. 14, 2023

Related U.S. Application Data
(60) Provisional application No. 63/346,316, filed on May 26, 2022.

(51) Int. Cl. H05K 7/20; G06F 1/20

(52) U.S. Cl. CPC H05K 7/20209; H05K 7/20172; G06F 1/206

(57) ABSTRACT

Aspects of the subject technology provide for dynamic noise control for electronic devices. For example, a dynamically adjustable limit on component noise may be generated based on ambient noise, based on other device-generated sound, based on a state of an audio output device, and/or based on an application being actively utilized at an electronic device. As one example, an electronic device may increase a limit on a sound-generating component of an electronic device when the electronic device determines that a user of the electronic device is engaged in a sound-tolerant activity. As another example, an electronic device may decrease a limit on a sound-generating component of an electronic device when the electronic device determines that a user of the electronic device is engaged in a sound-sensitive activity.

### CROSS REFERENCE TO RELATED APPLICATIONS

This application claims the benefit of priority to U.S. Provisional Patent Application No. 63/346,316, entitled, “Dynamic Noise Control for Electronic Devices”, filed on May 26, 2022, the disclosure of which is hereby incorporated herein in its entirety.

### TECHNICAL FIELD

The present description relates generally to electronic devices, including, for example, dynamic noise control for electronic devices.

### BACKGROUND

An electronic device may include a fan for cooling the electronic device. The fan is generally controlled based on the temperature of the device, with the fan speed increasing when the device temperature rises and more cooling is needed.

### BRIEF DESCRIPTION OF THE DRAWINGS

Certain features of the subject technology are set forth in the appended claims. However, for purpose of explanation, several embodiments of the subject technology are set forth in the following figures.

FIG. 1 illustrates a block diagram of an example electronic device with a sound-generating component in accordance with one or more implementations.

FIG. 2 illustrates a block diagram of the example electronic device of FIG. 1 generating sounds in an environment with ambient sounds in accordance with one or more implementations.

FIG. 3 illustrates a block diagram of the example electronic device of FIG. 1 receiving device and ambient sounds with device microphones in accordance with one or more implementations.

FIG. 4 illustrates a block diagram of the example electronic device of FIG. 1 controlling a sound-generating component based on device and ambient sounds and device information in accordance with one or more implementations.

FIG. 5 illustrates a block diagram of an example architecture for dynamic noise control in accordance with one or more implementations.

FIG. 6 illustrates a block diagram of an example sound analyzer of the architecture of FIG. 5 in accordance with one or more implementations.

FIG. 7 illustrates a flow diagram of example process for dynamic noise control in accordance with one or more implementations.

FIG. 8 illustrates a flow diagram of another example process for dynamic noise control in accordance with one or more implementations.

FIG. 9 illustrates an example electronic system with which aspects of the subject technology may be implemented in accordance with one or more implementations.

### DETAILED DESCRIPTION

The detailed description set forth below is intended as a description of various configurations of the subject technology and is not intended to represent the only configurations in which the subject technology can be practiced. The appended drawings are incorporated herein and constitute a part of the detailed description. The detailed description includes specific details for the purpose of providing a thorough understanding of the subject technology. However, the subject technology is not limited to the specific details set forth herein and can be practiced using one or more other implementations. In one or more implementations, structures and components are shown in block diagram form in order to avoid obscuring the concepts of the subject technology.

An electronic device may include one or more components that generate sound. The sound-generating components can include components that generate the sound as a primary function of the component (e.g., a speaker), or components that generate sounds as a byproduct of the primary function of the component (e.g., fans, blowers, haptic components, piezoelectric actuators, motors, other air-moving components, and/or other components with moving parts). In some cases, a sound-generating component may be a thermal management component, such as a fan or other air moving component of the electronic device.

In a case in which the sound-generating component is a thermal management component, it may be desirable to operate the component at a high setting that generates a high amount of byproduct noise when the device temperature is high. However, for sounds that are generated by fans or other components for which the sound is a byproduct of the primary function of the component can be distracting or annoying to users of electronic devices. Thus, it can also be desirable to limit the amount of noise generated by a sound-generating component, (e.g., to improve a user experience by limiting or reducing sounds that can be distracting or annoying to the user), such as by limiting the operation of the component. However, limiting the operation of the component to, for example, a maximum operational setting can, in some use cases, unnecessarily restrict the operation of the component when the sound from the component may not be audible or may not be distracting due to other sounds from the device or in the environment of the device, and/or due to an activity being performed by or with the device.

In one or more implementations, aspects of the subject technology can provide for control of a sound-generating component, such as a thermal management component, in a way that opportunistically increases the operational limits on the sound-generating components based on ambient noise, device noise, and/or current operations of an electronic device.

In one or more implementations, aspects of the subject technology may provide a dynamically adjustable maximum limit on component noise, such as noise from a cooling fan. For example, a fan limit can be dynamically adjusted based on ambient noise, based on other device-generated sound (e.g., speaker output), based on a state of an audio output device (e.g., an active noise cancellation (ANC) or transparency state of an earbud or headphone), and/or an application or other process or service that is being currently utilized at an electronic device. As examples, adjusting the fan limit based on device activity may include decreasing a fan speed or a maximum fan speed when a meditation application is running on and/or being utilized at the electronic device and when fan noise may be less tolerable to a user, or increasing the fan speed or maximum fan speed when a fitness application is running on and/or being utilized at the electronic device and when fan noise may thus be more tolerable.

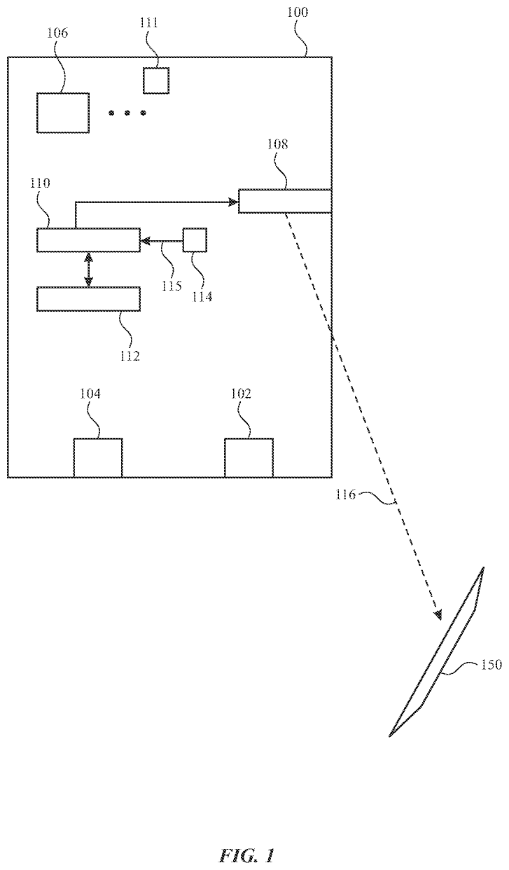

FIG. 1 illustrates an example electronic device in accordance with one or more implementations. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

In the example of FIG. 1, an electronic device 100 includes a sound-generating component 108. The sound-generating component 108 may be, for example, a thermal management component such as a fan (e.g., a cooling fan), a haptic component (e.g., a piezoelectric actuator), a blower, another air-moving component, a motor, or any other device that generates sound as an unintended audio output (e.g., as a byproduct of the primary function of the component). In the example of FIG. 1, the electronic device 100 also includes a speaker 102, configured to generate sound as a primary function of the speaker. Although a single speaker 102 and a single sound-generating component 108 are shown in FIG. 1, it is appreciated that the electronic device 100 may include one, two, three, more than three, or generally any number of speakers and/or sound-generating components.

As shown in FIG. 1, electronic device 100 may also include one or more microphones, such as microphone 104 and microphone 106. In the example of FIG. 1, microphone 106 is disposed nearer to the sound-generating component 108 than the microphone 104 is to the sound-generating component 108. However, in other implementations, the microphones of the electronic device 100 may be arranged in other arrangements, such as equidistant from the sound-generating component 108 or otherwise distributed with respect to the sound-generating component 108. Although two microphones are shown in FIG. 1, it is appreciated that the electronic device 100 may include two, three, more than three, or generally any number of microphones. In one or more implementations, it may have been previously determined that, among the several microphones of the electronic device, the microphone 104 receives a minimum amount of component noise from the sound-generating component 108. In one or more implementations, the electronic device 100 may include one or more input sensors, such as input sensor 111. As examples, input sensor 111 may be or include one or more cameras, one or more depth sensors, one or more touch sensors, one or more device-motion sensors, one or more sensors for detecting user gestures, such as hand gestures, and/or one or more sensors for detecting features and/or motions of one or both eyes of a user, such as sensors for tracking a gaze location at which the user of the electronic device is gazing (e.g., a location within a user interface of an application being actively utilized at the electronic device 100).

Electronic device 100 may be implemented as, for example, a portable computing device such as a desktop computer, a laptop computer, a smartphone, a peripheral device (e.g., a digital camera, headphones), a tablet device, a smart speaker, a set-top box, a content streaming device, a wearable device such as a watch, a band, a headset device, wireless headphones, one or more wireless earbuds (or any in-ear, against the ear or over-the-ear device), and/or the like, or any other appropriate device that includes one or more sound-generating components.

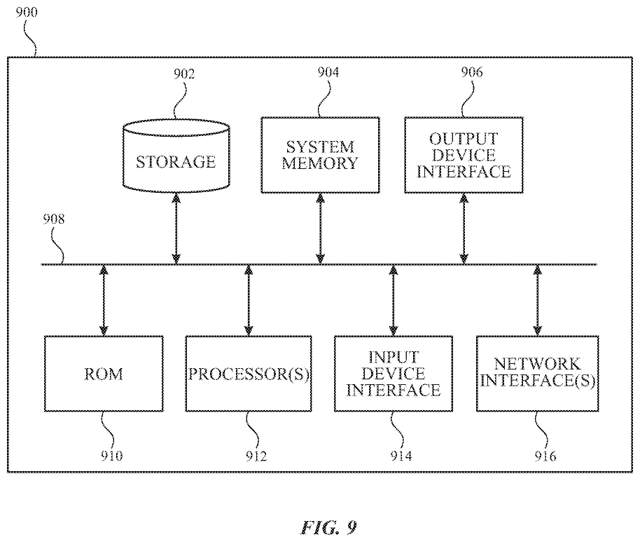

Although not shown in FIG. 1, electronic device 100 may include one or more wireless interfaces, such as one or more near-field communication (NFC) radios, WLAN radios, Bluetooth radios, Zigbee radios, cellular radios, and/or other wireless radios. Electronic device 100 may be, and/or may include all or part of, the electronic system discussed below with respect to FIG. 9.

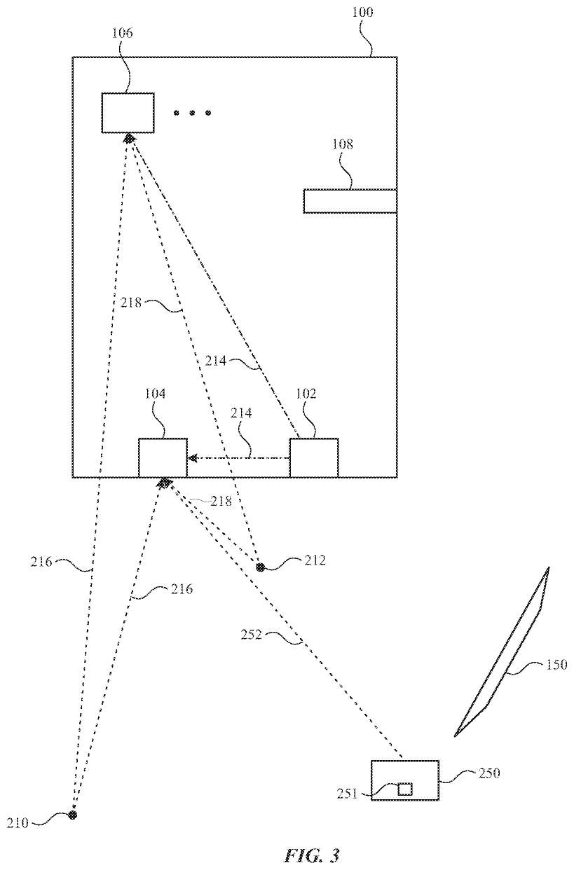

In the example of FIG. 1, processing circuitry 110 of the electronic device 100 is driving the sound-generating component 108. For example, processing circuitry 110 of the electronic device 100, using power from a power source of the electronic device 100 such as a battery of the electronic device, may drive a sound-generating component 108, such as to operate a cooling fan for cooling of the electronic device 100. In one or more implementations, the electronic device 100 may include one or more sensors, such as sensor 114. For example, sensor 114 may be a thermal sensor, such as thermistor, that monitors the temperature of one or more components and/or parts of the electronic device 100. As illustrated in FIG. 3, the processing circuitry 110 may control the operation of the sound-generating component 108 based, in part, on sensor information 115 from the sensor 114. For example, the processing circuitry 110 may increase a setting (e.g., a fan speed) of the sound-generating component 108 (e.g., a fan) when the sensor information 115 from the sensor 114 indicates an increase in temperature of the electronic device 100 or an increase in processing power usage of the electronic device 100.

In one or more implementations, the processing circuitry 110 may also control the fan speed of a fan, or another operational setting of another sound-generating component based on power information (e.g., processing power usage information, processing cycles information) and/or other information such as telemetry information received from one or more remote devices and/or systems (e.g., including environmental information, such as an ambient temperature and/or an ambient humidity, and/or including state information for one or more other devices or systems, such as paired device or system). For example, processing circuitry 110 may increase the fan speed of a fan of the electronic device 100 in anticipation of an increase in temperature, such as based on an increase of processing cycles of the processing circuitry 110 that is anticipated to raise the temperature of the processing circuitry 110. As shown, the electronic device 100 may include memory 112. The processing circuitry 110 may, in one or more implementations, execute one or more applications, software, and/or other instructions stored in the memory 112 (e.g., to implement one or more of the processes, methods, activities, and/or operations described herein).

As shown in FIG. 1, sound 116 from the sound-generating component 108 may be received at an ear 150 of a user of the electronic device 100. For this reason, it may be desirable to limit a setting (e.g., a fan speed) of the sound-generating component 108 to limit the amount of sound 116 that is heard by the user.

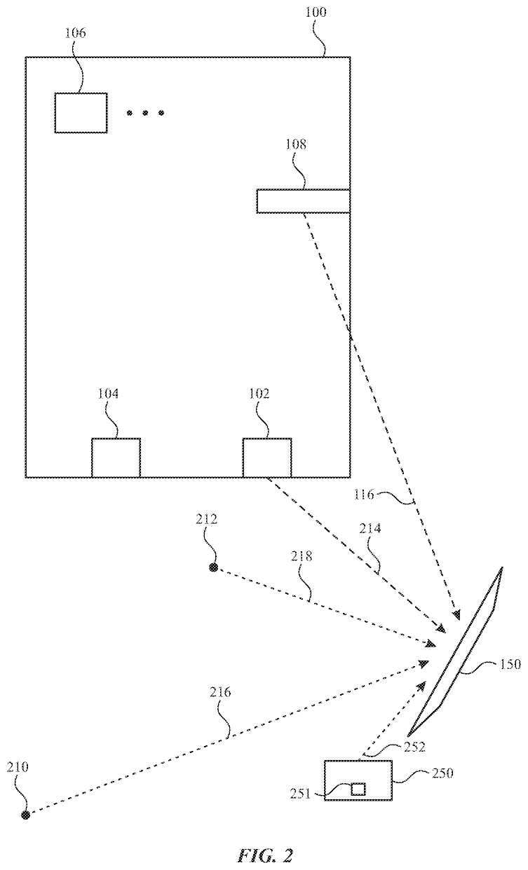

However, as illustrated in FIG. 2, the sound-generating component 108 may be operated at a time when other sources of sound are present. As illustrative examples, FIG. 2 shows sound 214 generated by the speaker 102 (e.g., as a primary function of the speaker) and various sources of ambient sound generated by noise sources in the environment of the electronic device 100. For example, while the electronic device 100 is driving the sound-generating component 108, one or more far-field audio sources such as a far-field audio source 210 and/or one or more near-field audio sources, such as near-field audio source 212 may generate sounds (e.g., sounds 216 and 218, respectively) that are received at the ear 150 of the user.

In various use cases, the sound 214 may correspond to music content or video content at the electronic device or streaming from a server, voice content from a remote participant in an audio call or an audio and/or video conferencing session, or any other audio content. In one or more use cases, the near-field audio source 212 may be the user of the electronic device 100 and the sound 218 may be sound corresponding to the voice of the user. In one or more implementation, the far-field audio source 210 may be or include various ambient sounds such as a voice of a person or multiple people other than the user of the electronic device 100, an air conditioner or room fan, a vacuum cleaner, a dishwasher, a washing machine, a vehicle, an aircraft, a watercraft, traffic, wind, or any other environmental noise source. In the example of FIG. 2, sound 252 is also generated by an audio output device 250, which may be an external speaker, a headphone, an earbud, or other audio output device that is communicatively coupled to (e.g., and/or paired with) the electronic device 100. In the example of FIG. 2, the audio output device 250 is a separate device from the electronic device 100, and the audio output device 250 and the and the electronic device 100 have separate housings within which the components of the respective devices are enclosed. In one or more other implementations, the audio output device 250 may form a portion of the electronic device 100 (e.g., the audio output device 250 may be encompassed by the same housing as the electronic device 100).

Because the sound 214 of the speaker 102, the sound 218 of the near-field audio source 212, the sound 216 of the far-field audio source, and/or the sound 252 of the audio output device 250 may be received at the ear 150 of the user along with (e.g., at the same time as) the sound 116 from the sound-generating component 108, it may, in some uses cases, be possible raise a limit on the sound 116 from the sound-generating component 108 (e.g., because the sound 116 from the sound-generating component 108 may be masked by the sound 214 of the speaker 102, the sound 218 of the near-field audio source 212, the sound 216 of the far-field audio source, and/or the sound 252 of the audio output device 250).

In order to allow the processing circuitry 110 to increase the limit on the amount of the sound 116 that can be generated by the sound-generating component 108, the electronic device 100 may detect and process one or more other sounds generated by the electronic device 100 and/or in the environment of the electronic device 100. For example, FIG. 3 illustrates how the sound 214 from the speaker 102, the sound 218 of the near-field audio source 212, the sound 216 of the far-field audio source, and/or the sound 252 of the audio output device 250 may also be received at the microphone 104 and/or the microphone 106 of the electronic device 100.

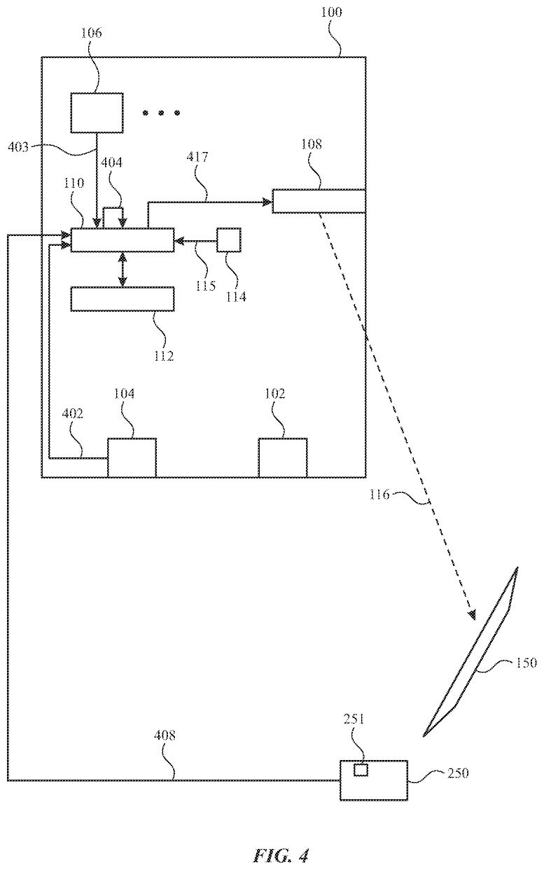

As illustrated in FIG. 4, the processing circuitry 110 may receive a microphone signal 402 from the microphone 104 (e.g., generated in response to the sound 214 from the speaker 102, the sound 218 of the near-field audio source 212, the sound 216 of the far-field audio source, and/or the sound 252 of the audio output device 250 as shown in FIG. 3) and/or a microphone signal 403 from the microphone 106 (e.g., generated in response to the sound 214 from the speaker 102, the sound 218 of the near-field audio source 212, the sound 216 of the far-field audio source, and/or the sound 252 of the audio output device 250 as shown in FIG.). As shown in FIG. 4, the processing circuitry 110 may also receive state information 408 from the audio output device 250, and/or may obtain (e.g., generated and/or receive) information 404 indicating one or more operations being performed by the electronic device 100 and/or by a user of the electronic device 100. In the example of FIG. 4, the processing circuitry 110 modifies the control signal 417 to modify the operation of the sound-generating component 108 (e.g., to reduce or increase the amount of the sound 116 generated by the sound-generating component 108.

As examples, the information 404 may include audio output information corresponding to the sound 214 being output by the speaker 102, information indicating an operational mode of the electronic device 100 (e.g., a work mode, a home mode, a focus mode, a sleep mode, a meditation mode, a fitness or workout mode, a driving mode, etc.), and/or information indicating an application running on the electronic device 100 and/or being actively utilized (e.g., by a user) at the electronic device 100. As indicated in FIG. 4, the information 404 may be information generated by and/or internally obtainable by the processing circuitry 110 itself (e.g., regarding the operations of the electronic device 100 that are being controlled and/or managed by the processing circuitry 110 itself, such as executing applications, operating the speaker 102, or the like).

In one or more implementations, the information 404 may include information indicating whether an application that is being currently utilized at the electronic device 100 is a noise-sensitive application (e.g., a meditation application displaying an interface of a meditation application, an electronic reader or e-book application, a word processor application, or other application that may be utilized by a user during a noise-sensitive activity such as meditating, reading, writing, etc.) or a noise-tolerant application (e.g., a fitness application displaying an interface of a fitness application or workout application, a media player application or gaming application outputting sound 214 with the speaker 102, an application receiving voice input from a user of the electronic device, a mapping application, a karaoke application, or other application that may be utilized by a user of the electronic device during a noise-tolerant activity such as working out, listening to loud music or video or gaming content, speaking into the electronic device, driving, singing, etc.).

In one or more implementations, the processing circuitry 110 may reduce an operational setting of the sound-generating component 108 (e.g., and thereby decrease the noise level of the sound-generating component 108) when the information 404 indicates that the application that is being currently utilized is a noise-sensitive application and/or that an associated current user activity is a sound-sensitive activity. In one or more implementations, the processing circuitry 110 may increase an operational setting of the sound-generating component 108 (e.g., and thereby increase the noise level of the sound-generating component 108) when the information 404 indicates that the application is a sound-tolerant application and/or that an associated current user activity is a sound-tolerant activity.

In one or more implementations, a sound-sensitive application may be an application that, when the application is being actively utilized, the application and/or the user of the electronic device (e.g., based on average and/or population based measurements of sound generation during active utilization of the application) do not generate sound above a threshold amount of sound. In one or more implementations, a sound-tolerant application may be an application that, when the application is being actively utilized, the application and/or the user of the electronic device (e.g., based on average and/or population based measurements of sound generation during active utilization of the application) generate sound above a threshold amount of sound. In one or more implementations, a sound-sensitive application may be an application that, when the application is being actively utilized, the application and/or the user of the electronic device (e.g., based on average and/or population based measurements of motion during active utilization of the application) move less than a threshold amount of motion, such as when the user and the user's electronic device are relatively motionless during a meditation activity. In one or more implementations, a sound-sensitive application may be an application that, when the application is being actively utilized, the application and/or the user of the electronic device (e.g., based on average and/or population based measurements of motion during active utilization of the application) move more than a threshold amount of motion, such as when the user and/or the user's electronic device are in motion during a workout or while playing a video game.

In one or more implementations, the information 404 may include a type (e.g., a meditation type, an electronic reader type, a media output type, a word processor type, a messaging type, a social media type, a mail client type, a web browsing type, a voice assistant type, a voice recorder type, a dictation type, a media player type, a fitness type, a workout type, a conferencing type, a chat type, a navigation type, etc.) of an application being actively utilized at the electronic device 100. In some examples, the processing circuitry 110 may reduce an operational setting of the sound-generating component 108 (e.g., and thereby decrease the noise level of the sound-generating component 108) when the application type indicates a sound-sensitive application, such as for a meditation type, an electronic reader type, a word processor type, a messaging type, a mail client type, or a web browsing type. In other examples, the processing circuitry 110 may increase an operational setting (e.g., and thereby increase the noise level) of the sound-generating component 108 when the application type indicates a sound-tolerant application, such as a noise generator type, a media output type, a social media type, a voice assistant type, a voice recorder type, a dictation type, a media player type, a fitness type, a workout type, a conferencing type, a chat type, or a navigation type.

In one or more implementations, the processing circuitry 110 may determine that an application is being actively utilized at the electronic device 100 based on input sensor information from the input sensor 111. For example, the processing circuitry 110 may determine that an application is being actively utilized by detecting a user interaction with the application (e.g., with a user interface of the application). In one or more implementations, the user interface of the application may occupy a portion of a display of the electronic device or may be operated in a full screen mode in which the user interface of the application occupies substantially the entire display of the electronic device 100. In one or more implementations, the processing circuitry may determine that an application is being actively utilized when the application is running in the full screen mode. In one or more implementations, the processing circuitry 110 may determine that the application is being actively utilized by detecting a user interaction with the user interface of the application. As examples, a user interaction that may be detected using the input sensor 111 may include one or more of a user contact with a touchscreen or other touch-sensitive surface of the electronic device at a location within a user interface of the application, a user gesture such as a hand gesture at or toward a location within a user interface of the application, a user gaze detected at location within a user interface of the application, user motion of the electronic device or a controller of the electronic device while a user interface of the application is displayed, a voice input to the application, and/or any other user interaction with a user interface of the application.

In one or more implementations, the state information 408 may include information indicating whether the audio output device 250 is in use, information indicating whether the audio output device 250 is being worn by a user of the electronic device 100, information indicating whether the audio output device 250 is outputting sound (e.g., from a speaker of the audio output device), information indicating whether the audio output device 250 is in a noise cancellation mode (e.g., an active noise cancellation, or ANC, mode), or other information indicating a state of the audio output device 250. In one or more implementations, audio output device 250 may also provide a microphone signal from a microphone 251 of the audio output device 250 to the processing circuitry 110.

As described in further detail hereinafter, the processing circuitry 110 may operate the sound-generating component 108 based on the microphone signal 402, the microphone signal 403, the state information 408, the information 404, and/or the sensor information 115 from the sensor 114.

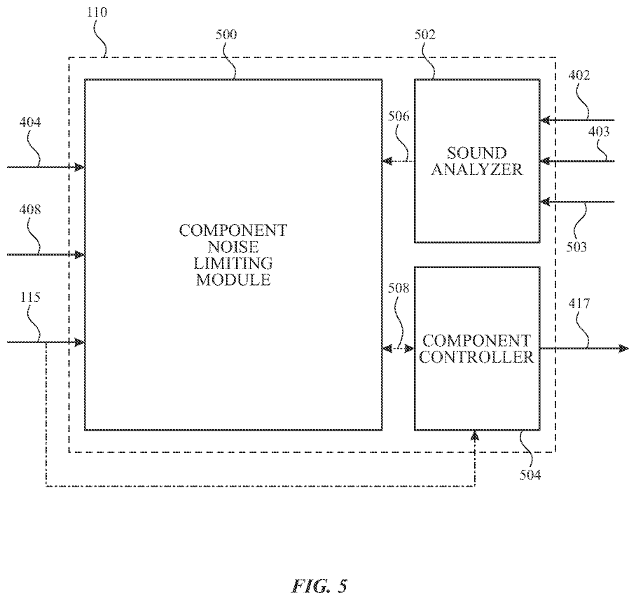

FIG. 5 illustrates a block diagram of an example architecture for performing dynamic noise control in accordance with one or more implementations. For explanatory purposes, the architecture of FIG. 5 is primarily described herein as being implemented by the electronic device 100 of FIG. 1. However, the architecture of FIG. 5 is not limited to the electronic device 100 of FIG. 1, and may be implemented may be implemented by one or more other components and other suitable devices. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

As shown, the architecture of FIG. 5 may include a component noise limiting module 500, a sound analyzer 502, and/or a component controller 504. In one or more implementations, component noise limiting module 500, the sound analyzer 502, and/or the component controller 504 of FIG. 5 may be implemented in software (e.g., subroutines and code executed by processing circuitry 110 as illustrated in FIG. 5), hardware (e.g., an Application Specific Integrated Circuit (ASIC), a Field Programmable Gate Array (FPGA), a Programmable Logic Device (PLD), a controller, a state machine, gated logic, discrete hardware components, or any other suitable devices), and/or a combination of both. In one or more implementations, some or all of the depicted components may share hardware and/or circuitry, and/or one or more of the depicted components may utilize dedicated hardware and/or circuitry. Additional features and functions of these modules according to various aspects of the subject technology are further described in the present disclosure.

In the example of FIG. 5, the component noise limiting module 500 receives inputs, including the information 404 (e.g., including information associated with an application that is being actively utilized at the electronic device 100), the state information 408, and the sensor information 115 described above in connection with FIGS. 1-4. As shown, the sound analyzer 502 may receive one or more microphone signals, such as the microphone signal 402 from the microphone 104 and/or the microphone signal 403 from the microphone 106. As illustrated in FIG. 5, in one or more implementations, the sound analyzer 502 may also, optionally, receive a microphone signal 503, such as from a microphone of another device, such as a paired device having a microphone (e.g., the microphone 251 of the audio output device 250). For example, in one or more implementations in which the audio output device 250 is an earbud or a headphone having a microphone, the microphone 251 of the audio output device 250 may be the microphone that is closest to the user's ear 150 and thus provides the best estimation of the sound that is received at the user's ear 150 and/or that is furthest from the sound-generating component 108 and thus receives a least or minimal amount of the sound 116 from the sound-generating component 108. However, in other implementations, the microphone signal 503 may be omitted if the user is not using an audio output device 250 that is separate from the speakers (e.g., the speaker 102) of the electronic device 100, and the microphone 106 may be the microphone that is closest to the user's ear and/or furthest from the sound-generating component 108. In one or more implementations, the sound analyzer 502 may be configured to receive and/or select a sound input (e.g., the microphone signal 503 or the microphone signal 402) from a microphone (e.g., the microphone 104 or the microphone 251 of the audio output device 250) that has been determined, from among the several microphones of the electronic device 100 and/or the audio output device 250, to receive a least (e.g., a minimum) amount of the sound 116 from the sound-generating component 108.

As illustrated in FIG. 5, the sound analyzer 502 may receive one or more microphone signals from one or more microphones as input(s), and generate, as output and based on the one or more microphone signals, a recommendation 506 (e.g., a setting recommendation or limit recommendation) for the sound-generating component 108. As shown, the component noise limiting module 500 may receive the recommendation 506 from the sound analyzer 502 along with the information 404, the state information 408, and/or the sensor information 115. The component noise limiting module 500 may then generate one or more control parameters, such as a control parameter 508, for the sound-generating component 108 based on a combination of the recommendation 506, the information 404, the state information 408, and/or the sensor information 115.

In one or more implementations, the component noise limiting module 500 may generate the control parameter of 508 based on the combination of the recommendation 506, the information 404, the state information 408, and/or the sensor information 115, by modifying the recommendation 506 based on the information 404, the state information 408, and/or the sensor information 115, by overriding the recommendation 506 based on the information 404, the state information 408, and/or the sensor information 115, or by generating a control parameter based on the information 404, the state information 408, and/or the sensor information 115 and then modifying the generated control parameter based on the recommendation 506.

In one illustrative example, the component noise limiting module 500 may determine, based on the state information 408, that the audio output device 250 is in a noise cancelling mode of operation (e.g., in a scenario in which the audio output device 250 is a headphone or an earbud that is being worn by a user of the electronic device 100 and is in an ANC mode), and may increase a recommended setting for the sound-generating component 108 in the recommendation 506 (e.g., increase a recommended fan speed or fan speed limit for a fan of the electronic device), may forego decreasing a recommended setting for the sound-generating component 108 in the recommendation 506 (e.g., even if the component noise is determined to be currently high), or may override the setting for the sound-generating component 108 in the recommendation 506 and set the control parameter 508 to a maximum control parameter (e.g., to allow increased and/or maximum operation of the sound-generating component 108 while the user is wearing and using noise-cancelling hardware and is thus less likely to be able to hear component noise).

In another illustrative example, the component noise limiting module 500 may determine, based on the information 404, that the electronic device 100 is operating in a meditation mode of operation or is operating a meditation application, and may reduce a recommended setting for the sound-generating component 108 in the recommendation 506 (e.g., reduce a recommended fan speed or fan speed limit for a fan of the electronic device), or may override the setting for the sound-generating component 108 in the recommendation 506 and set the control parameter 508 to a minimum control parameter (e.g., to reduce the sound 116 generated by the sound-generating component 108 while the electronic device 100 is in the meditation mode or is operating the meditation application and while the user of the electronic device 100 is likely less tolerant of and/or able to hear component noise). In one illustrative use case, a user may be using a meditation app (or other sound-sensitive application) running on the electronic device 100, the sound analyzer 502 may determine that the component noise of the sound-generating component 108 is high and recommend a reduction in the component setting to reduce the component noise, and the component noise limiting module 500 may forego making the recommended reduction in response to determining that the user is wearing earbuds (e.g., audio output device 250) in an ANC mode.

In another illustrative example, the component noise limiting module 500 may determine, based on the information 404, that the electronic device 100 is operating in a workout mode of operation or is operating a fitness application, and may increase a setting for the sound-generating component 108 in the recommendation 506 (e.g., by increasing a recommended fan speed or fan speed limit for a fan of the electronic device), or may override the setting for the sound-generating component 108 in the recommendation 506 and set the control parameter 508 to a maximum control parameter (e.g., to allow increased and/or maximum operation of the sound-generating component 108 while the user of the electronic device 100 is likely engaged in a workout and likely more tolerant of and/or able to hear component noise). In any of these examples, the sensor information 115 may also be used to increase or decrease a component setting recommended by the sound analyzer 502 and/or modified or overridden by the component noise limiting module 500, and/or to select from a set of allowable settings generated by the component noise limiting module 500 based on the microphone signal(s), the information 404, and/or the state information 408.

The component noise limiting module 500 may provide the control parameter 508 to the component controller 504. The component controller 504 may then generate the control signal 417 for controlling the operation of the sound-generating component 108 based on the control parameter 508, as described above in connection with FIG. 4. In various implementations, the control parameter 508 can be a setting (e.g., an operational setting, such as a fan speed) of the sound-generating component), or can be a limit (e.g., an operational limit, such as a fan speed limit) below which the component controller 504 can use to determine the fan speed (e.g., based on the sensor information 115). For example, in an implementation in which the control parameter 508 is a limit, the component controller may select an operational setting from a set of allowable operational settings for the sound-generating component 108 that are each below the limit provided in the control parameter 508.

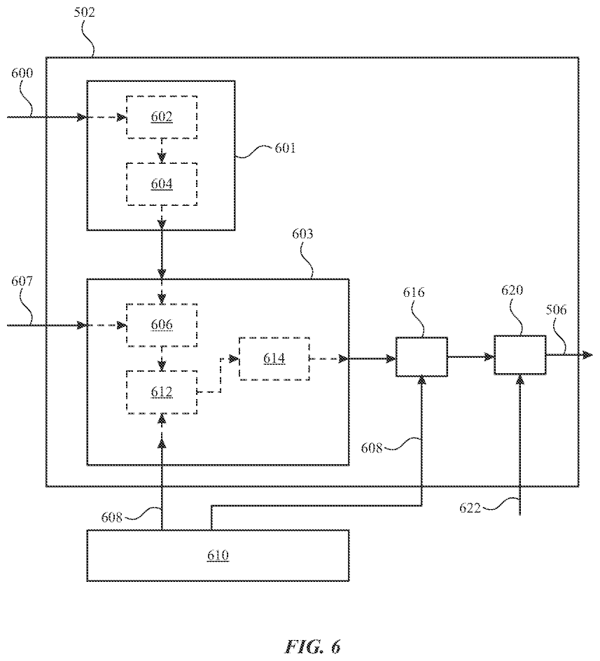

FIG. 6 illustrates a block diagram of an example architecture for sound analyzer 502 of FIG. 5, in accordance with one or more implementations. For explanatory purposes, the architecture of FIG. 6 is primarily described herein as being implemented by the electronic device 100 of FIG. 1. However, the architecture of FIG. 6 is not limited to the electronic device 100 of FIG. 1, and may be implemented may be implemented by one or more other components and other suitable devices. Not all of the depicted components may be used in all implementations, however, and one or more implementations may include additional or different components than those shown in the figure. Variations in the arrangement and type of the components may be made without departing from the spirit or scope of the claims as set forth herein. Additional components, different components, or fewer components may be provided.

As shown in the example of FIG. 6, the sound analyzer 502 may include a pre-filtering block 601, a noise filter block 603, a loudness estimator 616, and a component parameter generator 620. In one or more implementations, the pre-filtering block 601, the noise filter block 603, the loudness estimator 616, and/or the component parameter generator 620 may be implemented in software (e.g., subroutines and code executed by processing circuitry 110 as illustrated in FIG. 5), hardware (e.g., an Application Specific Integrated Circuit (ASIC), a Field Programmable Gate Array (FPGA), a Programmable Logic Device (PLD), a controller, a state machine, gated logic, discrete hardware components, or any other suitable devices), and/or a combination of both. In one or more implementations, some or all of the depicted components may share hardware and/or circuitry, and/or one or more of the depicted components may utilize dedicated hardware and/or circuitry. Additional features and functions of these modules according to various aspects of the subject technology are further described in the present disclosure.

In the example of FIG. 6, the sound analyzer receives a microphone signal 600 from a microphone. As examples, the microphone signal 600 may be the microphone signal 402 from the microphone 104, the microphone signal 403 from the microphone 106, or the microphone signal 503 from the audio output device 250.

In one or more implementations, the pre-filtering block 601 may generate a power spectrum from the microphone signal 600, and may apply one or more filters to the generated power spectrum. For example, the pre-filtering block may optionally include a power spectrum generator 602 and a time filter 604. In one or more implementations, the pre-filtering block 601 (e.g., the power spectrum generator 602) may convert the microphone signal to frequency space (e.g., by applying a transform, such as a Fourier transform, to the microphone signal). For example, the power spectrum generator 602 may output a frequency-space version of the microphone signal, such a power spectrum that indicates the power in the microphone signal in each of one or more frequency bins (also referred to herein as frequency bands). In one or more implementations, the pre-filtering block may apply a time filter (e.g., the time filter 604) to the power spectrum (e.g., from the power spectrum generator 602) to smooth the frequency-space version of the microphone signal in time. For example, the time filter 604 may filter the power in each frequency bin at each time frame with one or more power measurements in the same frequency bin obtained at one or more adjacent time frames, to smooth power spectrum in time. In this way, the time filter 604 may blend or smooth signal components of the microphone signal that have been generated by transient or short-term sounds (e.g., a door knock or a dog bark).

In one or more implementations, the pre-filtered signal from the pre-filtering block 601 (e.g., the time-smoothed power spectrum) may be provided to the noise filter block 603. In one or more implementations, the noise filter block 603 may optionally include a component noise remover 606, a noise floor tracker 612, and/or a frequency spreader 614. In one or more implementations, the noise filtering block 603 may remove a portion of the pre-filtered output from the pre-filtering block 601 that includes component noise, may identify a noise floor from the component-noise removed pre-filtered output, and/or may apply a frequency filter to the component-noise removed pre-filtered output to reduce the signal from monotonal or narrow frequency sounds. For example, as shown in FIG. 6, the noise filtering block 603 (e.g., the component noise remover 606) may also receive a current setting 607 (e.g., a current fan speed) for the sound-generating component 108, and may also obtain a component power spectrum 608 from a library, such as a component power spectrum library 610. For example, the component power spectrum library 610 may be a library of previously measured power spectra of the sound-generating component 108, each corresponding to a component setting of the sound-generating component 108, and each obtained by measuring the sound of the sound-generating component 108 implemented across a group, or a population, of devices. The component power spectrum 608 obtained by the noise filtering block 603 (e.g., by the component noise remover 606) from the component power spectrum library 610 may be the component power spectrum previously measured for the sound-generating component 108 when the sound-generating component 108 was operated with the current setting 607 at which the sound-generating component 108 is currently being operated.

The noise filtering block 603 (e.g., the component noise remover 606) may then subtract the power spectrum of the sound-generating component 108 from the time-smoothed power spectrum generated from the microphone signal 600. In this way, an estimate of the sound from the sound-generating component 108 that may have been received by the microphone that generated the microphone signal 600 and included in the microphone signal 600, can be removed from the power spectrum generated from the microphone signal 600.

As illustrated in FIG. 6, the component-noise-removed power spectrum may then be provided to a noise floor tracker 612. The noise floor tracker 612 may use a relatively long time constant (e.g., a time constant of one second, two seconds, or several seconds) to estimate a minimum amount of sound received, in each frequency bin or frequency band, over a time period corresponding to that long time constant. For example, the noise floor tracker 612 may select, for each frequency bin or frequency band, a minimum of the powers measured in that frequency bin or frequency band, from among a set of time-filtered, component-noise-removed power spectra obtained within the time period corresponding to the time constant. In this way, the noise floor tracker 612 can generate a noise floor (e.g., noise floor power spectrum) that accounts for (e.g., effectively ignores) any loud but transient sounds in the microphone signals 600.

For example, if a user of the electronic device 100 is operating the electronic device 100 in a room in which an air conditioner is operating and a kitchen timer or an alarm clock in the room generates a relatively loud (e.g., louder than the sound of the air conditioner) audible alert for a brief period of time, the noise floor tracker 612 can estimate the noise floor corresponding to the sound of the air conditioner in the room without being affected by the transient sound of the alarm. In this way, the noise floor tracker 612 can help the sound analyzer 502 (e.g., and the component noise limiting module 500) control the sound-generating component 108 in a smooth and consistent manner that avoids rapid increases and/or decreases in the settings of the sound-generating component 108 when transient, or short-term, noises occur in the environment of the electronic device 100.

As shown in FIG. 6, the noise floor (e.g., noise floor power spectrum) generated by the noise floor tracker 612 can optionally be provided to a frequency spreader 614. The frequency spreader 614 may apply a filter across one or more of the frequency bins. For example, the frequency spreader 614 can blend a noise floor power in each frequency bin with the noise floor powers in one or more adjacent frequency bins (e.g., weighting the noise floor powers in the one or more adjacent frequency bins according to the filter). In this way, the frequency spreader 614 can help the sound analyzer 502 (e.g., and the component noise limiting module 500) operate the sound-generating component 108 in a smooth and consistent manner that is unaffected by single-frequency, narrow-frequency, or monotonal sounds (e.g., sounds with power in only one of the frequency bins, or two adjacent frequency bins). For example, a sound with a single tone in the room in which the user of the electronic device 100 is operating the electronic device 100 may not be a masking sound for the relatively white noise of a cooling fan of the electronic device 100. For this reason, the sound analyzer 502 and/or the component noise limiting module 500 may be arranged (e.g., by including the frequency spreader 614) to avoid modifying settings of the sound-generating component 108 due to the presence of narrow frequency sounds received in the microphone signal 600.

As shown in FIG. 6, the noise filtering block 603 (e.g., the frequency spreader 614) may provide an output (e.g., the frequency-smoothed noise floor power spectrum) to a loudness estimator 616. As shown, the loudness estimator 616 may also receive one or more component power spectra 608 from the component power spectrum library 610. The loudness estimator 616 may then use the noise floor power spectrum obtained from the microphone signal 600, and the component power spectra 608 of the sound-generating component 108 from the component power spectrum library 610, to determine an estimated component loudness 618 for the sound-generating component 108. The estimated component loudness 618 may be an estimate of the loudness of the sound-generating component 108 in the current noise environment (e.g., represented by the frequency-smoothed noise floor power spectrum) of the electronic device 100.

For example, in an environment in which the microphone signal 600 includes signal components corresponding to the sound 214 from the speaker 102, the sound 218 from the near-field audio source 212, the sound 216 from the far-field audio source 210, and/or the sound 252 from the audio output device 250, the estimated component loudness 618 of the sound-generating component 108 may be less than the estimated loudness of the sound-generating component 108 would be in the absence of the sound 214 from the speaker 102, the sound 218 from the near-field audio source 212, the sound 216 from the far-field audio source 210, and/or the sound 252 from the audio output device 250, even if the amount of sound 116 generated by the sound-generating component 108 is the same. That is, the loudness estimator 616 may provide an estimated component loudness 618 of sound 116 from the sound-generating component 108 in the presence of a current amount of masking noise for that sound. In one or more implementations, the loudness estimator 616 may obtain component power spectra for multiple potential component settings for the sound-generating component 108, and generate an estimated component loudness(es) 618 for each of the multiple component settings.

The estimated component loudnesses 618 for the various component settings may be provided to the component parameter generator 620. As shown, the component parameter generator 620 may generate the recommendation 506 for output from the sound analyzer 502 to the component noise limiting module 500, based on the estimated component loudness(es) 618 and an audibility threshold 622. For example, the component parameter generator 620 may select, as the recommendation 506, a component parameter (e.g., a component setting or a component setting limit, such as a fan speed or a fan speed limit) corresponding to the estimated component loudness 618 that is nearest to and below the audibility threshold 622, in one or more implementations. In one or more implementations, the audibility threshold 622 is a fixed threshold (e.g., determined based on the noise tolerance of a group, or population, of users). In these implementations, the loudness estimator 616 facilitates accurate comparison of component loudness(es) 618 to the fixed audibility threshold in various noise environments by comparing the component noise to the noise floor in the environments to generate the component loudness, before the component parameter generator 620 compares the component loudness to the audibility threshold.

In one or more other implementations, the audibility threshold 622 may be a dynamic threshold that is determined based on the information 404 and/or the state information 408 described above in connection with FIG. 4. For example, the audibility threshold 622 may be increased when the state information 408 indicates that the audio output device 250 is being worn and is being operated in an ANC mode, may be increased when the information 404 indicates that the electronic device 100 is being operated in a noise-tolerant mode of operation or that a noise-tolerant application is being currently utilized, or may be decreased when the information 404 indicates that the electronic device 100 is being operated in a noise-sensitive mode of operation or that a noise-sensitive application is being currently utilized. In this way, in one or more implementations, the sound analyzer 502 may generate component setting limits and/or component settings for the sound-generating component 108, based on the microphone signals, the information 404 (e.g., information associated with an application that is being actively utilized), and/or the state information 408, without the separate use of the component noise limiting module 500 in one or more implementations.

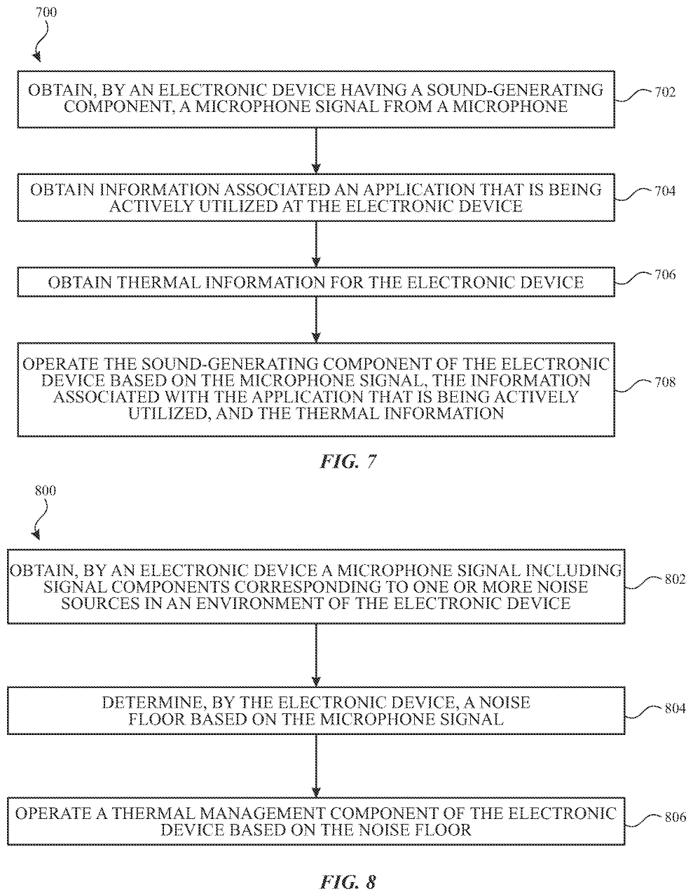

FIG. 7 illustrates a flow diagram of an example process for dynamic noise control, in accordance with one or more implementations. For explanatory purposes, the process 700 is primarily described herein with reference to the electronic device 100 of FIG. 1. However, the process 700 is not limited to the electronic device 100 of FIG. 1, and one or more blocks (or operations) of the process 700 may be performed by one or more other components and other suitable devices. Further for explanatory purposes, the blocks of the process 700 are described herein as occurring in serial, or linearly. However, multiple blocks of the process 700 may occur in parallel. In addition, the blocks of the process 700 need not be performed in the order shown and/or one or more blocks of the process 700 need not be performed and/or can be replaced by other operations.

In the example of FIG. 7, at block 702, an electronic device (e.g., electronic device 100) having a sound-generating component (e.g., sound-generating component 108), may obtain a microphone signal from a microphone. For example, the sound-generating component may include a fan (e.g., a cooling fan) of the electronic device, a motor of the electronic device, a haptic component of the electronic device, or any other component of the electronic device that generates sound during operation of the component. For example, the sound-generating component may generate sound (e.g., noise) as a byproduct of a primary function of the component.

At block 704, the electronic device may obtain information associated with the application that is being actively utilized at the electronic device. In one or more implementations, the information associated with the application that is being actively utilized may include information indicating whether the application is a noise-sensitive application or a noise-tolerant application. In one or more implementations, the information associated with the application that is being actively utilized may include a type of an application performing the current activity. In one or more implementations, the information associated with the application that is being actively utilized may include some or all of the information 404 discussed herein.

In one or more implementations, the application that is being actively utilized may be running in a full-screen mode at the electronic device. For example, a full-screen mode may be a mode in which substantially an entire display of the electronic device is occupied by a user interface of the application. In one or more implementation, the process 700 may also include determining that the application is being actively utilized based on a detected user interaction with the application. As examples, the detected user interaction may include one or more of a user contact with a touchscreen or other touch-sensitive surface of the electronic device at a location that corresponds to a location within a user interface of the application, a user gesture such as a hand gesture at or toward a location within a user interface of the application, a user gaze detected at location within a user interface of the application, user motion of the electronic device or a controller of the electronic device while a user interface of the application is displayed, a voice input to the application, or any other user interaction with a user interface of the application.

At block 706, the electronic device may obtain thermal information for the electronic device. As examples, the thermal information may include a current or predicted temperature of the electronic device, a current or predicted temperature of an environment of the electronic device, and/or a current or predicted temperature of a component of the electronic device. In one or more implementations, the thermal information may be obtained in, and/or derived from, one or more sensor signals, such as the sensor information 115 from the sensor 114. In one or more implementations, the thermal information may include power information, such as processing power information (e.g., an increase in processor usage) that can lead to an upcoming temperature change for the electronic device and/or one or more components thereof.

At block 708, the electronic device may operate the sound-generating component of the electronic device based on the microphone signal, the information associated with the application that is being actively utilized, and the thermal information. For example, operating the sound-generating component of the electronic device may include determining a new setting (e.g., control parameter 508) for the sound-generating component of the electronic device based on the microphone signal (e.g., the microphone signal 402, the microphone signal 403, the microphone signal 503, and/or the microphone signal 600 described herein), the information associated with the application that is being actively utilized (e.g., the information 404), the thermal information (e.g., the sensor information 115), a current setting (e.g., current setting 607) of the sound-generating component, and a pre-determined noise profile (e.g., a component power spectrum 608 from the component power spectrum library 610) of the sound-generating component (e.g., as described herein in connection with FIGS. 5 and 6).

In one or more implementations, the process 700 may also include obtaining state information (e.g., state information 408) for an audio output device (e.g., audio output device 250) that is communicatively coupled to the electronic device. In one or more implementations, operating the sound-generating component of the electronic device may also include determining the new setting for the sound-generating component of the electronic device based on the state information for the audio output device. In one illustrative example, the electronic device may increase a fan speed or a fan speed limit for a fan of the electronic device, responsive to determining that a user of the electronic device is wearing headphones that are operating in a noise-cancelling mode of operation. In this illustrative example, the electronic device may decrease the fan speed or the fan speed limit for the fan of the electronic device, responsive to determining that the user has removed the headphones and/or that the headphones are no longer operating in the noise-cancelling mode of operation.

In one or more implementations, the microphone signal includes a signal component corresponding to a voice of a user of the electronic device, and operating the sound-generating component of the electronic device includes operating the sound-generating component based a detection of the voice of the user. For example, the electronic device may increase a setting or a limit of the sound-generating component when the voice of the user is detected in the microphone signal, and/or may decrease the setting or the limit of the sound generating component when the voice of the user is not detected in the microphone signal. In this way, the electronic device can allow and/or use a higher setting that generates more component noise when the user is talking and may be less able to hear, or less sensitive to, the sound of the sound-generating component.

In one or more implementations, operating the sound-generating component of the electronic device based on the microphone signal, the information associated with the application that is being actively utilized, and the thermal information may include determining a noise level (e.g., determining a noise floor by the noise floor tracker 612, such as by determining a noise floor spectrum across several frequency bins or frequency bands) associated with an ongoing noise source in the microphone signal, and modifying the operation of the sound-generating component based on the noise level associated with the ongoing noise source in the microphone signal. In one or more implementations, operating the sound-generating component of the electronic device based on the microphone signal, the information associated with the application that is being actively utilized, and the thermal information may also include foregoing modifying the operation of the sound-generating component when a transient noise source is received in the microphone signal (e.g., by time smoothing the microphone signals using the time filter 604 and/or by using a relatively long time constant in the noise floor tracker 612, as discussed herein in connection with FIG. 6).

In one or more implementations, operating the sound-generating component of the electronic device based on the microphone signal, the information associated with the application that is being actively utilized, and the thermal information at block 708 may include increasing an operational limit for the sound-generating component based on a determination that the information associated with the application that is being actively utilized indicates that the application is a noise-tolerant application and/or that a user of the electronic device is engaged in a noise-tolerant activity (e.g., a workout or listening to loud music). In one or more implementations, operating the sound-generating component of the electronic device based on the microphone signal, the information associated with the application that is being actively utilized, and the thermal information at block 708 may include decreasing an operational limit for the sound-generating component based on a determination that the information associated with the application that is being actively utilized indicates that the application is a noise-sensitive application and/or that a user of the electronic device is engaged in a noise-sensitive activity (e.g., reading or meditating).

FIG. 8 illustrates a flow diagram of another example process for dynamic noise control for an electronic device, in accordance with one or more implementations. For explanatory purposes, the process 800 is primarily described herein with reference to the electronic device 100 of FIG. 1. However, the process 800 is not limited to the electronic device 100 of FIG. 1, and one or more blocks (or operations) of the process 800 may be performed by one or more other components and other suitable devices. Further for explanatory purposes, the blocks of the process 800 are described herein as occurring in serial, or linearly. However, multiple blocks of the process 800 may occur in parallel. In addition, the blocks of the process 800 need not be performed in the order shown and/or one or more blocks of the process 800 need not be performed and/or can be replaced by other operations.

In the example of FIG. 8, at block 802, an electronic device (e.g., electronic device 100) may obtain a microphone signal including signal components corresponding to one or more noise sources in an environment of the electronic device. As examples, the noise sources may include a speaker (e.g., speaker 102) of the electronic device, one or more near-field audio sources 212, one or more far-field audio sources 210, and/or an audio output component 250 as discussed herein.

In one or more implementations, obtaining the microphone signal may include obtaining the microphone signal with one (e.g., microphone 104) of several microphones (e.g., the microphone 104 and the microphone 106) of the electronic device that has been determined to detect a minimum amount of component noise from the thermal management component. In one or more other implementations, obtaining the microphone signal may include obtaining the microphone signal with a microphone of another device, such as a microphone (e.g., microphone 251) of an audio output device (e.g., audio output device 250) that is communicatively coupled (e.g., via a wired or wireless connection) to the electronic device.

At block 804, the electronic device may determine a noise floor based on the microphone signal. In one or more implementations, determining the noise floor may include determining a band-noise floor in each of several frequency bands (e.g., frequency bins). In one or more implementations, the electronic device (e.g., frequency spreader 614 of the sound analyzer 502) may also perform a frequency spreading operation on the band-noise floors to generate a frequency-spread noise floor for each frequency band.

In one or more implementations, the electronic device (e.g., loudness estimator 616) may also determine, for each of several component noise levels (e.g., as defined in several predetermined component power spectra 608) each corresponding to one of several component settings of a thermal management component (e.g., fan speeds of a fan), a respective noise difference between the noise floor and the respective component noise level. For example, the respective noise differences may each correspond to an estimated component loudness 618 of the sound-generating component, if the sound-generating component were to be operated at the corresponding one of the several component setting in the current noise environment of the electronic device.

At block 806, the electronic device may operate the thermal management component (e.g., sound-generating component 108) of the electronic device based on the noise floor. For example, the thermal management component may be a fan of the electronic device, and operating the thermal management component of the electronic device based on the noise floor may include increasing or decreasing a fan speed of the fan (e.g., and/or increasing or decreasing a limit on the fan speed) based on an increase or decrease of the noise floor.

In one or more implementations, operating the thermal management component of the electronic device based on the noise floor may include selecting (e.g., by component parameter generator 620) one of the several component settings having a corresponding component noise level (e.g., a corresponding component loudness 618) that is nearest to and below a threshold (e.g., the audibility threshold discussed herein in connection with FIG. 6).

In one or more implementations, an electronic device (e.g., electronic device 100) may operate a thermal management component, such as the sound-generating component 108, based on information associated with an application that is being actively utilized, such as information 404 (e.g., without determining a noise floor). For example, the electronic device obtain information associated with the application that is being actively utilized, and operate the thermal management component based at least in part the information associated with the application that is being actively utilized. The electronic device may operate the thermal management component based on the information associated with the application that is being actively utilized and based on thermal information for the electronic device. For example, the electronic device may raise or lower a fan speed of a fan of the electronic device based on the thermal information (e.g., a temperature of the electronic device and/or a component thereof, and/or a processing power usage of the electronic device and/or a component thereof), up to a fan limit that is determined based on the information associated with the application that is being actively utilized (e.g., a relatively low fan limit in circumstances in which the information associated with the application that is being actively utilized indicates that the application is a noise-sensitive application, or a relatively higher fan limit when the information associated with the application that is being actively utilized indicates that the application is a noise-tolerant application). In one or more use cases, the electronic device may operate the thermal management component based the information associated with the application that is being actively utilized by increasing an operational limit for the thermal management component based on a determination that the information associated with the application that is being actively utilized indicates that a user of the electronic device is engaged in a noise-tolerant activity.

As described above, one aspect of the present technology is the gathering and use of data available from specific and legitimate sources for processing user information in association with providing dynamic noise control for electronic devices. The present disclosure contemplates that in some instances, this gathered data may include personal information data that uniquely identifies or can be used to identify a specific person. Such personal information data can include voice data, speech data, audio data, demographic data, location-based data, online identifiers, telephone numbers, email addresses, home addresses, data or records relating to a user's health or level of fitness (e.g., vital signs measurements, medication information, exercise information), date of birth, or any other personal information.

The present disclosure recognizes that the use of such personal information data, in the present technology, can be used to the benefit of users. For example, the personal information data can be used for dynamic noise control for electronic devices. Accordingly, use of such personal information data may facilitate transactions (e.g., on-line transactions). Further, other uses for personal information data that benefit the user are also contemplated by the present disclosure. For instance, health and fitness data may be used, in accordance with the user's preferences to provide insights into their general wellness, or may be used as positive feedback to individuals using technology to pursue wellness goals.

The present disclosure contemplates that those entities responsible for the collection, analysis, disclosure, transfer, storage, or other use of such personal information data will comply with well-established privacy policies and/or privacy practices. In particular, such entities would be expected to implement and consistently apply privacy practices that are generally recognized as meeting or exceeding industry or governmental requirements for maintaining the privacy of users. Such information regarding the use of personal data should be prominently and easily accessible by users, and should be updated as the collection and/or use of data changes. Personal information from users should be collected for legitimate uses only. Further, such collection/sharing should occur only after receiving the consent of the users or other legitimate basis specified in applicable law. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations which may serve to impose a higher standard. For instance, in the US, collection of or access to certain health data may be governed by federal and/or state laws, such as the Health Insurance Portability and Accountability Act (HIPAA); whereas health data in other countries may be subject to other regulations and policies and should be handled accordingly.

Despite the foregoing, the present disclosure also contemplates examples in which users selectively block the use of, or access to, personal information data. That is, the present disclosure contemplates that hardware and/or software elements can be provided to prevent or block access to such personal information data. For example, in the case of providing dynamic noise control for electronic devices, the present technology can be configured to allow users to select to “opt in” or “opt out” of participation in the collection of personal information data during registration for services or anytime thereafter. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing identifiers, controlling the amount or specificity of data stored (e.g., collecting location data at city level rather than at an address level), controlling how data is stored (e.g., aggregating data across users), and/or other methods such as differential privacy.

Therefore, although the present disclosure broadly covers use of personal information data to implement one or more various disclosed examples, the present disclosure also contemplates that the various examples can also be implemented without the need for accessing such personal information data. That is, the various examples of the present technology are not rendered inoperable due to the lack of all or a portion of such personal information data.

FIG. 9 illustrates an electronic system 900 with which one or more implementations of the subject technology may be implemented. The electronic system 900 can be, and/or can be a part of, one or more of the electronic device 100 shown in FIG. 1. The electronic system 900 may include various types of computer readable media and interfaces for various other types of computer readable media. The electronic system 900 includes a bus 908, one or more processing unit(s) 912, a system memory 904 (and/or buffer), a ROM 910, a permanent storage device 902, an input device interface 914, an output device interface 906, and one or more network interfaces 916, or subsets and variations thereof.

The bus 908 collectively represents all system, peripheral, and chipset buses that communicatively connect the numerous internal devices of the electronic system 900. In one or more implementations, the bus 908 communicatively connects the one or more processing unit(s) 912 with the ROM 910, the system memory 904, and the permanent storage device 902. From these various memory units, the one or more processing unit(s) 912 retrieves instructions to execute and data to process in order to execute the processes of the subject disclosure. The one or more processing unit(s) 912 can be a single processor or a multi-core processor in different implementations.

The ROM 910 stores static data and instructions that are needed by the one or more processing unit(s) 912 and other modules of the electronic system 900. The permanent storage device 902, on the other hand, may be a read-and-write memory device. The permanent storage device 902 may be a non-volatile memory unit that stores instructions and data even when the electronic system 900 is off. In one or more implementations, a mass-storage device (such as a magnetic or optical disk and its corresponding disk drive) may be used as the permanent storage device 902.

In one or more implementations, a removable storage device (such as a floppy disk, flash drive, and its corresponding disk drive) may be used as the permanent storage device 902. Like the permanent storage device 902, the system memory 904 may be a read-and-write memory device. However, unlike the permanent storage device 902, the system memory 904 may be a volatile read-and-write memory, such as random access memory. The system memory 904 may store any of the instructions and data that one or more processing unit(s) 912 may need at runtime. In one or more implementations, the processes of the subject disclosure are stored in the system memory 904, the permanent storage device 902, and/or the ROM 910. From these various memory units, the one or more processing unit(s) 912 retrieves instructions to execute and data to process in order to execute the processes of one or more implementations.

The bus 908 also connects to the input and output device interfaces 914 and 906. The input device interface 914 enables a user to communicate information and select commands to the electronic system 900. Input devices that may be used with the input device interface 914 may include, for example, alphanumeric keyboards and pointing devices (also called “cursor control devices”). The output device interface 906 may enable, for example, the display of images generated by electronic system 900. Output devices that may be used with the output device interface 906 may include, for example, printers and display devices, such as a liquid crystal display (LCD), a light emitting diode (LED) display, an organic light emitting diode (OLED) display, a flexible display, a flat panel display, a solid state display, a projector, or any other device for outputting information. One or more implementations may include devices that function as both input and output devices, such as a touchscreen. In these implementations, feedback provided to the user can be any form of sensory feedback, such as visual feedback, auditory feedback, or tactile feedback; and input from the user can be received in any form, including acoustic, speech, or tactile input.

Finally, as shown in FIG. 9, the bus 908 also couples the electronic system 900 to one or more networks and/or to one or more network nodes, through the one or more network interface(s) 916. In this manner, the electronic system 900 can be a part of a network of computers (such as a LAN, a wide area network (“WAN”), or an Intranet, or a network of networks, such as the Internet. Any or all components of the electronic system 900 can be used in conjunction with the subject disclosure.

Implementations within the scope of the present disclosure can be partially or entirely realized using a tangible computer-readable storage medium (or multiple tangible computer-readable storage media of one or more types) encoding one or more instructions. The tangible computer-readable storage medium also can be non-transitory in nature.

The computer-readable storage medium can be any storage medium that can be read, written, or otherwise accessed by a general purpose or special purpose computing device, including any processing electronics and/or processing circuitry capable of executing instructions. For example, without limitation, the computer-readable medium can include any volatile semiconductor memory, such as RAM, DRAM, SRAM, T-RAM, Z-RAM, and TTRAM. The computer-readable medium also can include any non-volatile semiconductor memory, such as ROM, PROM, EPROM, EEPROM, NVRAM, flash, nvSRAM, FeRAM, FeTRAM, MRAM, PRAM, CBRAM, SONOS, RRAM, NRAM, racetrack memory, FJG, and Millipede memory.

Further, the computer-readable storage medium can include any non-semiconductor memory, such as optical disk storage, magnetic disk storage, magnetic tape, other magnetic storage devices, or any other medium capable of storing one or more instructions. In one or more implementations, the tangible computer-readable storage medium can be directly coupled to a computing device, while in other implementations, the tangible computer-readable storage medium can be indirectly coupled to a computing device, e.g., via one or more wired connections, one or more wireless connections, or any combination thereof.

Instructions can be directly executable or can be used to develop executable instructions. For example, instructions can be realized as executable or non-executable machine code or as instructions in a high-level language that can be compiled to produce executable or non-executable machine code. Further, instructions also can be realized as or can include data. Computer-executable instructions also can be organized in any format, including routines, subroutines, programs, data structures, objects, modules, applications, applets, functions, etc. As recognized by those of skill in the art, details including, but not limited to, the number, structure, sequence, and organization of instructions can vary significantly without varying the underlying logic, function, processing, and output.

While the above discussion primarily refers to microprocessor or multi-core processors that execute software, one or more implementations are performed by one or more integrated circuits, such as ASICs or FPGAs. In one or more implementations, such integrated circuits execute instructions that are stored on the circuit itself.

Those of skill in the art would appreciate that the various illustrative blocks, modules, elements, components, methods, and algorithms described herein may be implemented as electronic hardware, computer software, or combinations of both. To illustrate this interchangeability of hardware and software, various illustrative blocks, modules, elements, components, methods, and algorithms have been described above generally in terms of their functionality. Whether such functionality is implemented as hardware or software depends upon the particular application and design constraints imposed on the overall system. Skilled artisans may implement the described functionality in varying ways for each particular application. Various components and blocks may be arranged differently (e.g., arranged in a different order, or partitioned in a different way) all without departing from the scope of the subject technology.

It is understood that any specific order or hierarchy of blocks in the processes disclosed is an illustration of example approaches. Based upon design preferences, it is understood that the specific order or hierarchy of blocks in the processes may be rearranged, or that all illustrated blocks be performed. Any of the blocks may be performed simultaneously. In one or more implementations, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

As used in this specification and any claims of this application, the terms “base station”, “receiver”, “computer”, “server”, “processor”, and “memory” all refer to electronic or other technological devices. These terms exclude people or groups of people. For the purposes of the specification, the terms “display” or “displaying” means displaying on an electronic device.

As used herein, the phrase “at least one of” preceding a series of items, with the term “and” or “or” to separate any of the items, modifies the list as a whole, rather than each member of the list (i.e., each item). The phrase “at least one of” does not require selection of at least one of each item listed; rather, the phrase allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

The predicate words “configured to”, “operable to”, and “programmed to” do not imply any particular tangible or intangible modification of a subject, but, rather, are intended to be used interchangeably. In one or more implementations, a processor configured to monitor and control an operation or a component may also mean the processor being programmed to monitor and control the operation or the processor being operable to monitor and control the operation. Likewise, a processor configured to execute code can be construed as a processor programmed to execute code or operable to execute code.

Phrases such as an aspect, the aspect, another aspect, some aspects, one or more aspects, an implementation, the implementation, another implementation, some implementations, one or more implementations, an embodiment, the embodiment, another embodiment, some implementations, one or more implementations, a configuration, the configuration, another configuration, some configurations, one or more configurations, the subject technology, the disclosure, the present disclosure, other variations thereof and alike are for convenience and do not imply that a disclosure relating to such phrase(s) is essential to the subject technology or that such disclosure applies to all configurations of the subject technology. A disclosure relating to such phrase(s) may apply to all configurations, or one or more configurations. A disclosure relating to such phrase(s) may provide one or more examples. A phrase such as an aspect or some aspects may refer to one or more aspects and vice versa, and this applies similarly to other foregoing phrases.

The word “exemplary” is used herein to mean “serving as an example, instance, or illustration”. Any embodiment described herein as “exemplary” or as an “example” is not necessarily to be construed as preferred or advantageous over other implementations. Furthermore, to the extent that the term “include”, “have”, or the like is used in the description or the claims, such term is intended to be inclusive in a manner similar to the term “comprise” as “comprise” is interpreted when employed as a transitional word in a claim.

All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for”.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language claims, wherein reference to an element in the singular is not intended to mean “one and only one” unless specifically so stated, but rather “one or more”. Unless specifically stated otherwise, the term “some” refers to one or more. Pronouns in the masculine (e.g., his) include the feminine and neuter gender (e.g., her and its) and vice versa. Headings and subheadings, if any, are used for convenience only and do not limit the subject disclosure.

What is claimed is:

1. A method, comprising:
obtaining, by an electronic device having a sound-generating component, a microphone signal from a microphone;
obtaining information associated with an application that is being actively utilized at the electronic device;
obtaining thermal information for the electronic device; and
operating the sound-generating component of the electronic device based at least in part on the microphone signal, the information associated with the application that is being actively utilized, and the thermal information.

2. The method of claim 1, wherein the sound-generating component comprises a fan of the electronic device.

3. The method of claim 1, wherein the information associated with the application that is being actively utilized comprises information indicating whether the application is a noise-sensitive application or a noise-tolerant application.

4. The method of claim 1, wherein the application is running in a full-screen mode at the electronic device.

5. The method of claim 1, further comprising determining that the application is being actively utilized based on a detected user interaction with the application.

6. The method of claim 1, wherein operating the sound-generating component of the electronic device comprises determining a new setting for the sound-generating component of the electronic device based on the microphone signal, the information associated with the application that is being actively utilized, the thermal information, a current setting of the sound-generating component, and a pre-determined noise profile of the sound-generating component.

7. The method of claim 6, further comprising:
obtaining state information for an audio output device that is communicatively coupled to the electronic device; and
wherein operating the sound-generating component of the electronic device further comprises determining the new setting for the sound-generating component of the electronic device based on the state information for the audio output device.

8. The method of claim 1, wherein the microphone signal includes a signal component corresponding to a voice of a user of the electronic device, and wherein operating the sound-generating component of the electronic device comprises operating the sound-generating component based a detection of the voice of the user.

9. The method of claim 1, wherein operating the sound-generating component of the electronic device based at least in part on the microphone signal, the information associated with the application that is being actively utilized, and the thermal information comprises:
determining a noise level associated with an ongoing noise source in the microphone signal; and
modifying the operation of the sound-generating component based on the noise level associated with the ongoing noise source in the microphone signal.

10. The method of claim 9, wherein operating the sound-generating component of the electronic device based at least in part on the microphone signal, the information associated with the application that is being actively utilized, and the thermal information further comprises forgoing modifying the operation of the sound-generating component when a transient noise source is received in the microphone signal.

11. A method, comprising:
obtaining, by an electronic device, a microphone signal including signal components corresponding to one or more noise sources in an environment of the electronic device;
determining, by the electronic device, a noise floor based on the microphone signal; and
operating a thermal management component of the electronic device based on the noise floor.

12. The method of claim 11, wherein the thermal management component comprises a fan of the electronic device, and wherein operating the thermal management component of the electronic device based on the noise floor comprises increasing or decreasing a fan speed of the fan based on an increase or decrease of the noise floor.

13. The method of claim 11, wherein determining the noise floor comprises determining a band-noise floor in each of several frequency bands, and wherein the method further comprises performing a frequency spreading operation on the band-noise floors to generate a frequency-spread noise floor for each frequency band.

14. The method of claim 13, further comprising determining, for each of several component noise levels each corresponding to one of several component settings, a respective noise difference between the noise floor and the respective component noise level.

15. The method of claim 14, wherein operating the thermal management component of the electronic device based on the noise floor comprises selecting one of the several component settings having a corresponding component noise level that is nearest to and below a threshold.

16. The method of claim 11, wherein obtaining the microphone signal comprises obtaining the microphone signal with one of several microphones of the electronic device that has been determined to detect a minimum amount of component noise from the thermal management component.

17. The method of claim 11, wherein obtaining the microphone signal comprises obtaining the microphone signal with a microphone of an audio output device that is communicatively coupled to the electronic device.

18. An electronic device, comprising:
a thermal management component;
a memory, and
one or more processors configured to:
obtain information associated with an application that is being actively utilized at the electronic device; and
operate the thermal management component based at least in part the information associated with the application that is being actively utilized.

19. The electronic device of claim 18, wherein the information associated with the application that is being actively utilized comprises information indicating whether the application is a noise-sensitive application or a noise-tolerant application.

20. The electronic device of claim 18, wherein the information associated with the application that is being actively utilized comprises a type of the application.

21. The electronic device of claim 18, wherein the one or more processors are configured to operate the thermal management component based the information associated with the application that is being actively utilized by increasing an operational limit for the thermal management component based on a determination that the information indicates that a user of the electronic device is engaged in a noise-tolerant activity.
